(19) United States
(12) Patent Application Publication
(10) Pub. No.: US 2025/0326684 A1
(43) Pub. Date: Oct. 23, 2025

(54) GLASS CERAMIC STRUCTURE AND ELECTRONIC COMPONENT

(71) Applicant: Murata Manufacturing Co., Ltd., Nagaokakyo-shi (JP)

(72) Inventor: Yoshitaka ECHIKAWA, Nagaokakyo-shi (JP)

(21) Appl. No.: 19/254,349

(22) Filed: Jun. 30, 2025

Related U.S. Application Data
(63) Continuation of application No. PCT/JP2024/020069, filed on May 31, 2024.

(30) Foreign Application Priority Data
Jun. 16, 2023 (JP) 2023-099457

(51) Int. Cl. C03C 10/00

(52) U.S. Cl. CPC C03C 10/0036; C03C 2214/20; C03C 2214/30

(57) ABSTRACT

A glass-ceramic structure that includes first ceramic layers containing crystals and second ceramic layers containing crystals. The crystal content of the first ceramic layers is different from the crystal content of the second ceramic layers. The shortest distance in a thickness direction from a surface of the glass-ceramic structure to the second ceramic layer and the thickness of the second ceramic layer is ≤10. The crystals include at least one type selected from Al₂O₃, Zn₂SiO₄, ZnO, ZnAl₂O₄, BaAl₂Si₂O₈, ZnTiO₃, Al₂TiO₅, TiO₂, Mg₂SiO₄, MgSiO₃, and MgO. The percentage of a cross-sectional area of the crystals in the second ceramic layers relative to a cross-sectional area of the second ceramic layers is greater than a percentage of a cross-sectional area of the crystals in the first ceramic layers relative to a cross-sectional area of the first ceramic layers by a difference of 10 area % to 75 area %.

### CROSS REFERENCE TO RELATED APPLICATIONS

The present application is a continuation of International application No. PCT/JP2024/020069, filed May 31, 2024, which claims priority to Japanese Patent Application No. 2023-099457, filed Jun. 16, 2023, the entire contents of each of which are incorporated herein by reference.

### TECHNICAL FIELD

The present disclosure relates to glass-ceramic structures and electronic components.

### BACKGROUND ART

Low-temperature co-fired ceramic materials can be fired simultaneously with low-melting-point metal materials, which are relatively low in specific resistance, and thus can be used to form multilayer ceramic substrates with excellent high-frequency characteristics. These materials have been widely used as, for example, substrate materials for high-frequency modules in information and communication terminals.

Common low-temperature co-fired ceramic materials include glass-ceramic composite materials in which a ceramic material, such as Al₂O₃, is mixed with a B₂O₃—SiO₂ glass material. However, since these materials contain boron, which easily volatilizes during firing, they tend to produce substrates with compositional variations. To solve the problem, non-glass low-temperature co-fired ceramic materials free of boron have been proposed. However, fired ceramic bodies obtained by firing such low-temperature co-fired ceramic materials have a low fracture toughness value, and may fail to have desirable strength properties.

Patent Literature 1 discloses a fired ceramic body including respective crystal phases of quartz, alumina, fresnoite, sanbornite, and celsian. The relationship between the diffraction peak intensity A in the (201) plane of the fresnoite and the diffraction peak intensity B in the (110) plane of the quartz, measured by a powder X-ray diffractometry in the range of the diffraction peak angle 2θ=10° to 40°, satisfies A/B≥2.5.
Patent Literature 1: WO 2011/099397

### SUMMARY OF THE DISCLOSURE

In Patent Literature 1, the strength of a fired ceramic body is increased by precipitating crystals such as fresnoite crystals and celsian crystals throughout the entire ceramic layers. However, since crystals are precipitated throughout the entire structure, the electrical properties are limited to a certain extent, and stress cannot be applied to specific portions of the fired ceramic body. In addition, since the fired body of Patent Literature 1 is characterized by its material composition, the composition of the glass ceramic material needs to be adjusted in order to impart strength.

The present disclosure is intended to solve the above-mentioned problems, and an object thereof is to provide a glass-ceramic structure and an electronic component, in each of which fracture toughness is locally imparted.

A first glass-ceramic structure of the present disclosure includes: at least one first ceramic layer containing first crystals; and a second ceramic layer containing second crystals, a first crystal content of the first ceramic layer being different from a second crystal content of the second ceramic layer, the second ceramic layer being between first ceramic layers of the at least one first ceramic layer in a thickness direction of the glass-ceramic structure, or on a surface of the glass-ceramic structure, a shortest distance in the thickness direction from the surface of the glass-ceramic structure to the second ceramic layer and a thickness of the second ceramic layer satisfying a relationship (the shortest distance from the surface)/(the thickness of the second ceramic layer)≤10, the first ceramic layer having a composition of SiO₂: 45 wt % to 77.5 wt %, B₂O₃: 5 wt % to 20 wt %, Al₂O₃: 2.6 wt % to 20 wt %, ZnO: 2.7 wt % to 20 wt %, CuO: 0 wt % to 3.4 wt %, and BaO: 0 wt % to 10 wt %, the first and second crystals including at least one type of crystals selected from Al₂O₃, Zn₂SiO₄, ZnO, ZnAl₂O₄, BaAl₂Si₂O₈, ZnTiO₃, Al₂TiO₅, TiO₂, Mg₂SiO₄, MgSiO₃, and MgO, and a percentage of a cross-sectional area of the second crystals in the second ceramic layer relative to a cross-sectional area of the second ceramic layer is greater than a percentage of a cross-sectional area of the first crystals in the first ceramic layer relative to a cross-sectional area of the first ceramic layer by a difference of 10 area % to 75 area %.

A second glass-ceramic structure of the present disclosure includes: first ceramic layers containing first crystals; a second ceramic layer containing second crystals; and an internal electrode, a first crystal content of each of the first ceramic layers being different from a second crystal content of the second ceramic layer, the second ceramic layer being between the first ceramic layers in a thickness direction of the glass-ceramic structure, or on a surface of the glass-ceramic structure, the second ceramic layer and the internal electrode being adjacent to each other in the thickness direction, or at least one of the first ceramic layers being between the second ceramic layer and the internal electrode in the thickness direction, a shortest distance in the thickness direction from the internal electrode to the second ceramic layer and a thickness of the second ceramic layer satisfying a relationship (the shortest distance from the internal electrode)/(the thickness of the second ceramic layer)≤10, the first ceramic layer having a composition of SiO₂: 45 wt % to 77.5 wt %, B₂O₃: 5 wt % to 20 wt %, Al₂O₃: 2.6 wt % to 20 wt %, ZnO: 2.7 wt % to 20 wt %, CuO: 0 wt % to 3.4 wt %, and BaO: 0 wt % to 10 wt %, the first and second crystals including at least one type of crystals selected from Al₂O₃, Zn₂SiO₄, ZnO, ZnAl₂O₄, BaAl₂Si₂O₈, ZnTiO₃, Al₂TiO₅, TiO₂, Mg₂SiO₄, MgSiO₃, and MgO, a percentage of a cross-sectional area of the second crystals in the second ceramic layer relative to a cross-sectional area of the second ceramic layer is greater than a percentage of a cross-sectional area of the first crystals in the first ceramic layer relative to a cross-sectional area of the first ceramic layer by a difference of 10 area % to 75 area %.

The electronic component of the present disclosure includes the glass-ceramic structure.

The present disclosure can provide a glass-ceramic structure and an electronic component, in each of which fracture toughness is locally imparted.

### BRIEF DESCRIPTION OF THE DRAWINGS

FIG. 1 is a schematic cross-sectional view showing an example of a first glass-ceramic structure.

FIG. 2 is a schematic cross-sectional view showing another example of the first glass-ceramic structure.

FIG. 3A is a schematic cross-sectional view showing an example of the distribution of crystals in the glass-ceramic structure of FIG. 1.

FIG. 3B is a schematic cross-sectional view showing another example of the distribution of crystals in the glass-ceramic structure of FIG. 1.

FIG. 3C is a schematic cross-sectional view showing another example of the distribution of crystals in the glass-ceramic structure of FIG. 1.

FIG. 4 is a schematic cross-sectional view showing an example of a second glass-ceramic structure.

FIG. 5 is a schematic cross-sectional view showing an example of an electronic component.

FIG. 6 is a perspective view showing a method for measuring flexural strength of a glass-ceramic structure produced in the Examples.

FIG. 7 is a schematic cross-sectional view showing evaluation of the strength of the glass-ceramic structure produced in the Examples.

FIG. 8 is a schematic cross-sectional view showing evaluation of the strength of the glass-ceramic structure produced in the Examples.

### DESCRIPTION OF THE PREFERRED EMBODIMENTS

The first glass-ceramic structure, the second glass-ceramic structure, and the electronic component of the present disclosure are described hereinbelow. The present disclosure is not limited to the following preferred embodiments and may be suitably modified without departing from the gist of the present disclosure. Combinations of two or more preferred features described in the following preferred features are also within the scope of the present disclosure.

The first glass-ceramic structure of the present disclosure includes at least one first ceramic layer containing crystals and a second ceramic layer containing crystals, a crystal content of the first ceramic layer being different from a crystal content of the second ceramic layer. The second ceramic layer is disposed between first ceramic layers, which are included in the at least one first ceramic layer, in a thickness direction, or on a surface of the glass-ceramic structure.

In the first glass-ceramic structure, the at least one first ceramic layer constitutes a main body.

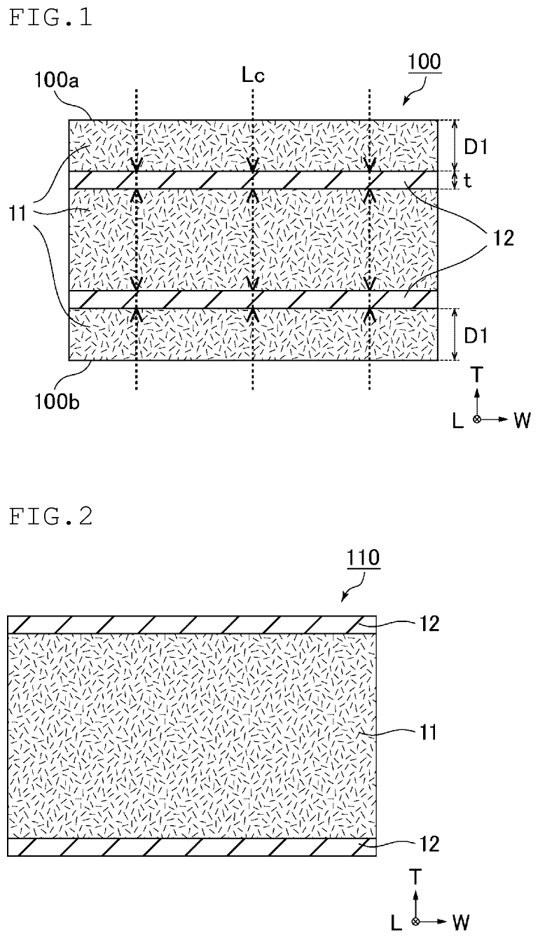

FIG. 1 is a schematic cross-sectional view showing an example of the first glass-ceramic structure. A glass-ceramic structure 100 shown in FIG. 1 is a stack including three first ceramic layers 11 and two second ceramic layers 12. In FIG. 1, the thickness of each of the second ceramic layers 12 is represented by t (μm), one of the second ceramic layers 12 is disposed at a shortest distance D1 from a main surface 100a, which is one of the main surfaces of the glass-ceramic structure 100, and the other second ceramic layer 12 is disposed at the shortest distance D1 from another main surface 100b of the glass-ceramic structure 100.

Here, although the number of the second ceramic layers is two, it may be one or three or more. The first glass-ceramic structure preferably includes two second ceramic layers.

The shortest distance in the thickness direction from each surface of the glass-ceramic structure to the corresponding second ceramic layer (hereinafter sometimes referred to as the “shortest distance from each surface”) and the thickness of the second ceramic layer satisfy the relationship represented by (the shortest distance from the surface)/(the thickness of the second ceramic layer)≤10. In the first glass-ceramic structure satisfying the relationship, the region where the second ceramic layer is formed has higher fracture toughness.

The shortest distance from the surface and the thickness of the second ceramic layer are determined as follows.

As shown in FIG. 1, first, a cross section in the width (W) and stacking (T) directions (WT cross section) passing through the center of the length (L) of the glass-ceramic structure is exposed by polishing. The polished surface is optionally subjected to etching. Then, the exposed cross section is observed with a scanning electron microscope.

A straight line Lc is drawn that extends in the stacking direction T of the first and second ceramic layers and passes through the center of the glass-ceramic structure. Next, straight lines parallel to the straight line Lc are drawn at equal intervals. Here, the spacing between adjacent straight lines may be determined to be about 5 to 10 times the thickness of the second ceramic layer to be measured. An equal number of straight lines are drawn on both sides of the line Lc. In other words, an odd number of straight lines, including the straight line Lc, is drawn in total. For example, three straight lines, including the straight line Lc, are drawn in total.

Next, on the straight lines including the straight line Lc, the shortest distance from the surface and the thickness of the second ceramic layer are measured. When the second ceramic layer has a defect and the first ceramic layers sandwiching the second ceramic layer are in contact with each other on any of the straight lines, or when the enlarged image of a measurement area is unclear, the shortest distance from the surface and the thickness of the second ceramic layer are measured on another straight line, which is drawn father from the straight line Lc. The resulting values are averaged to determine the shortest distance from the surface and the thickness of the second ceramic layer.

When the shortest distance in the thickness direction from the surface of the first glass-ceramic structure to the corresponding second ceramic layer (the shortest distance from each surface) is 0, the second ceramic layer is present on the surface of the first glass-ceramic structure (FIG. 2).

FIG. 2 is a schematic cross-sectional view showing another example of the first glass-ceramic structure. In FIG. 2, the two second ceramic layers 12 are disposed on the two main surfaces of a glass-ceramic structure 110, one on each surface.

The shortest distance in the thickness direction from each surface of the first glass-ceramic structure to the corresponding second ceramic layer is, for example, preferably 0 μm to 150 μm, more preferably 0 μm to 120 μm.

The thickness of the second ceramic layer is, for example, preferably 3 μm to 75 μm, more preferably 5 μm to 60 μm.

The shortest distance and the thickness of the second ceramic layer are not limited to the above ranges, and may be adjusted to satisfy the relationship. When the shortest distance is 0, that is, when the second ceramic layer is present on each surface of the first glass-ceramic structure, the value of (the shortest distance from each surface)/(the thickness of the second ceramic layer) is always 0 regardless of the thickness of the second ceramic layer. In this case, the thickness of the second ceramic layer is preferably 3 μm to 75 μm.

The first ceramic layer has a composition of SiO₂: 45 wt % to 77.5 wt %, B₂O₃: 5 wt % to 20 wt %, Al₂O₃: 2.6 wt % to 20 wt %, ZnO: 2.7 wt % to 20 wt %, CuO: 0 wt % to 3.4 wt %, and BaO: 0 wt % to 10 wt %. The composition is based on oxides.

The second ceramic layers (also referred to as crystalline layers) each include an amorphous portion with the same composition as that of the first ceramic layers described above, but the crystal content of the second ceramic layer is different from and higher than that of the first ceramic layer. The type of crystals whose content differs between the first and second ceramic layers is not limited. The crystals contained in the first ceramic layers, the crystals that are not contained in the first ceramic layers but are contained only in the second ceramic layers, or both of these crystals may be different in content between the first and second ceramic layers.

Examples of the crystals contained in the first ceramic layers include Al₂O₃ and ZnO crystals.

Examples of the crystals contained only in the second ceramic layers include Zn₂SiO₄, ZnAl₂O₄, BaAl₂Si₂O₈, ZnTiO₃, Al₂TiO₅, TiO₂, Mg₂SiO₄, MgSiO₃, and MgO.

The content of at least one type of crystals selected from the group consisting of Al₂O₃, Zn₂SiO₄, ZnO, ZnAl₂O₄, BaAl₂Si₂O₈, ZnTiO₃, Al₂TiO₅, TiO₂, Mg₂SiO₄, MgSiO₃, and MgO differs between the first and second ceramic layers. One or two or more types of crystals among these crystals may differ in content between the layers, and preferably, two or more thereof may differ in content between the layers.

The percentage of the cross-sectional area of the crystals in the second ceramic layer relative to the cross-sectional area of the second ceramic layer is greater than the percentage of the cross-sectional area of the crystals in the first ceramic layer relative to the cross-sectional area of the first ceramic layer by a difference (hereinafter sometimes referred to as a difference (d1)) of 10 area % to 75 area %. Here, each cross-sectional area of the crystals does not refer to the cross-sectional area of a certain type of crystals, but to the sum of the cross-sectional areas of all types of crystals. Since the difference (d1) is determined from the comparison based on the cross-sectional areas of all types of crystals, the percentage of a certain type of crystals in the second ceramic layer may be lower than the percentage of the same type of crystals in the first ceramic layer.

The percentage of the cross-sectional area of the crystals in the corresponding ceramic layer can be calculated, for example, as follows. First, a cross section of a specimen is observed using a scanning electron microscope (SEM) and an X-ray diffraction analyzer (XRD), and crystalline portions and amorphous portions are marked with specific colors. The marked crystalline portions are extracted using image analysis software or image editing software (Photoshop (®), ImageJ, etc.), black and white binarization is performed, and then the cross-sectional area of the crystalline portions and the cross-sectional area of the amorphous portions are determined. The percentage of the cross-sectional area of the crystals in the cross-sectional area of the corresponding ceramic layer is calculated by dividing the cross-sectional area of the crystalline portions by the sum of the cross-sectional area of the crystalline portions and the cross-sectional area of the amorphous portions.

The flexural strength of the glass-ceramic structure is higher when the difference (d1) is 10 areas to 75 area %, compared to when the difference (d1) is outside this range.

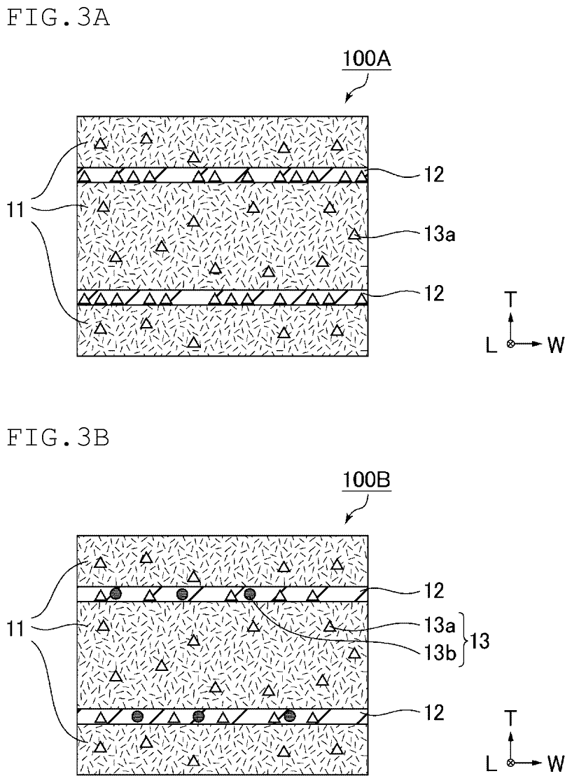

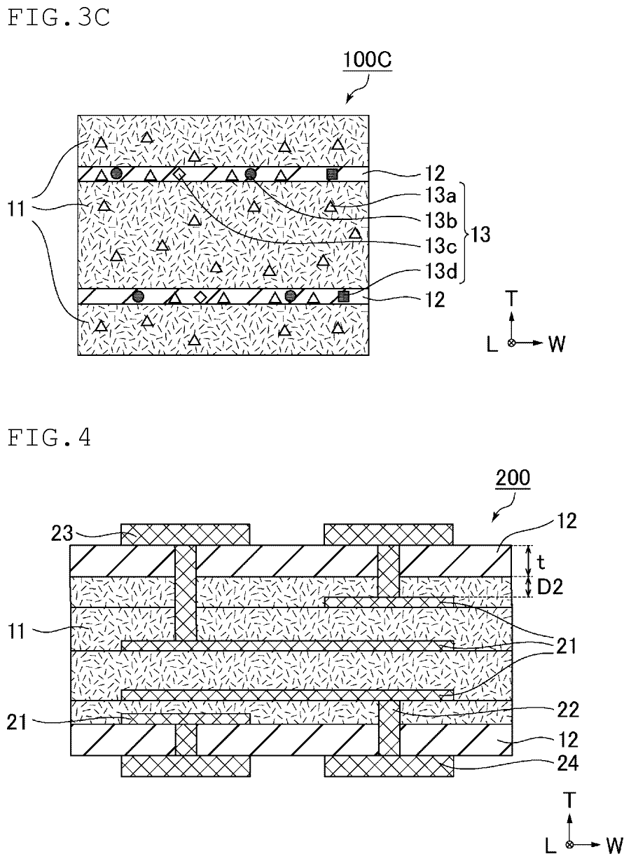

FIG. 3A is a schematic cross-sectional view showing an example of the distribution of crystals in the glass-ceramic structure of FIG. 1. FIG. 3B is a schematic cross-sectional view showing another example of the distribution of crystals in the glass-ceramic structure of FIG. 1. FIG. 3C is a schematic cross-sectional view showing another example of the distribution of crystals in the glass-ceramic structure of FIG. 1.

In a glass-ceramic structure 100A of FIG. 3A, the second ceramic layers 12 contain crystals 13a, which are also present in the first ceramic layers 11. The content of the crystals 13a is higher in the second ceramic layers 12 than in the first ceramic layers 11.

In a glass-ceramic structure 100B of FIG. 3B, the second ceramic layers 12 contain the crystals 13a and crystals 13b, and among these, the crystals 13a are also present in the first ceramic layers 11. The content of the crystals 13a is higher in the second ceramic layers 12 than in the first ceramic layers 11. The crystals 13b are present only in the second ceramic layers 12, without being present in the first ceramic layers 11. As long as the difference (d1) is within the above range, the content of the crystals 13a may be higher in the first ceramic layers 11 than in the second ceramic layers 12, or the crystals 13a may not be contained in the second ceramic layers 12.

In a glass-ceramic structure 100C of FIG. 3C, the second ceramic layers 12 contain the crystals 13a, the crystals 13b, crystals 13c, and crystals 13d, and among these, the crystals 13a are also present in the first ceramic layers 11. The content of the crystals 13a is higher in the second ceramic layers 12 than in the first ceramic layers 11. The crystals 13b, crystals 13c, and crystals 13d are present only in the second ceramic layers 12, without being present in the first ceramic layers 11. As long as the difference (d1) is within the above range, the content of the crystals 13a may be higher in the first ceramic layers 11 than in the second ceramic layers 12, or the crystals 13a may not be contained in the second ceramic layers 12.

In FIGS. 3A, 3B, and 3C, the first ceramic layers 11 contain only the crystals 13a, but may contain two or more types of crystals. The second ceramic layers 12 may contain four or more types of crystals.

The first glass-ceramic structure can be produced by the following method, for example.

### (1) Production of Green Sheet A

A glass-ceramic material for the first ceramic layer of the first glass-ceramic structure is mixed with a binder, a plasticizer, etc. to prepare a ceramic slurry A. Then, the ceramic slurry A is applied to a base film (e.g., a polyethylene terephthalate (PET) film) and then dried to produce a green sheet A.

### (2) Production of Green Sheet B

The same glass ceramic material as that used to produce the green sheet A is mixed with at least one filler component selected from the group consisting of Al₂O₃, BaTiO₃, ZnO, and Mg₂SiO₄ to prepare a raw material mixture. Here, since the higher the proportion of the filler component in the raw material mixture, the more crystals will precipitate in the second ceramic layer, the amount of the filler component is adjusted according to the desired proportion of crystals.

The raw material mixture is mixed with a binder, a plasticizer, etc., to prepare a ceramic slurry B. Then, the ceramic slurry B is applied to a base film and dried to produce a green sheet B.

### (3) Production and Firing of Multilayer Green Sheet

The green sheets A are stacked, and the green sheets B are disposed on opposing surfaces of the stack, one on each surface, or each green sheet B is disposed between the green sheets A to produce a multilayer green sheet. The multilayer green sheet is fired so that the green sheets A and the green sheets B are reacted to generate crystals in the entire or part of each green sheet B. As a result, the green sheet B is turned into a second ceramic layer. Thus, a glass-ceramic structure (multilayer ceramic substrate) as shown in FIG. 1 or FIG. 2 is obtained.

When Al₂O₃ is used as a filler component, Al₂O₃, BaAl₂Si₂O₈, and ZnAl₂O₄ crystals increase in the second ceramic layers.

When ZnO is used as a filler component, ZnAl₂O₃, ZnO, and Zn₂SiO₄ crystals increase in the second ceramic layer.

When Mg₂SiO₄ is used as a filler component, Mg₂SiO₄, MgSiO₃, and MgO crystals increase in the second ceramic layer.

When BaTiO₃ is used as a filler component, ZnTiO₃, Al₂TiO₅, BaAl₂Si₂O₈, and TiO₂ crystals increase in the second ceramic layer.

Compounds obtained by replacing Ba of a BaTiO₃ filler component with another alkaline earth metal can also be used as substitutes for the BaTiO₃ filler component, since they lead to precipitation of crystals with the same type of basic structure.

As an alternative to using the green sheet B, a pattern may be formed using the ceramic slurry B, which is the raw material for the green sheet B, on the green sheet A, the green sheets A with the pattern may be stacked, and the resulting stack may be fired. Thereby, the second ceramic layer can be formed on a surface of the glass-ceramic structure or in the glass-ceramic structure. The pattern may be formed by a method such as metal mask printing, chemical etching using chemicals, physical etching such as laser processing, inkjet printing, or spray coating.

The multilayer green sheet may be fired at any temperature as long as the glass ceramic materials of the green sheets A and B can be fired. For example, the firing temperature is 1000° C. or lower. The glass ceramic materials used in the present disclosure are each a low-temperature co-fired ceramic (LTCC) material.

The multilayer green sheet may be fired while being disposed between restraint green sheets. The restraint green sheets contain, as a main component, an inorganic material (e.g., Al₂O₃) that is substantially incapable of being fired at a firing temperature of the glass ceramic materials of the green sheets A and B. Thus, the restraint green sheets do not shrink when the multilayer green sheet is fired, and act to reduce or prevent shrinkage in the main surface direction of the multilayer green sheet. As a result, a structure with high dimensional accuracy can be obtained.

In the first glass-ceramic structure having the above-described configuration, the regions where the second ceramic layers are formed have higher fracture toughness. Crystals are precipitated in a concentrated manner on at least part of the opposing surfaces in the thickness direction of the glass-ceramic structure or at least part of regions near the opposing surfaces in the thickness direction. Thereby, compressive stress and tensile stress can be generated in various portions in the second ceramic layer. This allows stress induced by a localized load to be distributed, making it possible to increase fracture toughness.

Next, the second glass-ceramic structure is described.

The second glass-ceramic structure of the present disclosure includes first ceramic layers containing crystals, a second ceramic layer containing crystals, and an internal electrode, a crystal content of each of the first ceramic layers being different from a crystal content of the second ceramic layer. The second ceramic layer is disposed between the first ceramic layers in a thickness direction, or on a surface of the glass-ceramic structure. The second ceramic layer and the internal electrode are adjacent to each other in the thickness direction, or at least one of the first ceramic layers is disposed between the second ceramic layer and the internal electrode in the thickness direction.

In the second glass-ceramic structure, the first ceramic layers constitute a main body.

FIG. 4 is a schematic cross-sectional view showing an example of the second glass-ceramic structure. A glass-ceramic structure 200 shown in FIG. 4 is a stack including first ceramic layers 11 and second ceramic layers 12 (in FIG. 4, four first ceramic layers and two second ceramic layers). The second ceramic layers 12 are disposed on the opposing surfaces of the glass-ceramic structure 200 in the thickness direction, one on each surface.

Here, although the number of the second ceramic layers is two, it may be one or three or more. The second glass-ceramic structure preferably includes two second ceramic layers.

The glass-ceramic structure 200 includes internal electrodes 21 in two or more of the layers. Each internal electrode 21 is disposed either between two first ceramic layers 11 that are adjacent to each other in the thickness direction or between a first ceramic layer 11 and a second ceramic layer 12 that are adjacent to each other in the thickness direction. In FIG. 4, the thickness of each of the second ceramic layers 12 is represented by t (μm), one of the second ceramic layers 12 is disposed at a shortest distance D2 from the corresponding internal electrode 21 in the thickness direction, and a first ceramic layer 11 is disposed between the second ceramic layer 12 and the internal electrode 21. The other second ceramic layer 12 is disposed such that part of the second ceramic layer 12 is adjacent to the corresponding internal electrode 21 in the thickness direction.

The glass-ceramic structure 200 includes via conductors 22 and external electrodes 23 and 24. For example, these may define passive elements such as capacitors and inductors or may define connection wiring for electric connection between elements.

The external electrodes 23 are on one of main surfaces of the glass-ceramic structure 200.

The external electrodes 24 are on the other main surface of the glass-ceramic structure 200.

Each via conductor 22 is disposed to penetrate the corresponding first ceramic layer 11 and second ceramic layer 12 and plays a role in electrically connecting the corresponding internal electrode 21 and external electrode 23 or 24 to each other. The via conductor 22 may be disposed to electrically connect two internal electrodes 21.

In the second glass-ceramic structure, the shortest distance in the thickness direction from the internal electrode to the second ceramic layer and the thickness of the second ceramic layer satisfy the relationship represented by (the shortest distance from the internal electrode)/(the thickness of the second ceramic layer)≤10. In the second glass-ceramic structure satisfying the relationship, the regions where the second ceramic layers are formed have higher fracture toughness.

The thickness of the second ceramic layer can be determined in the same manner as for the first glass-ceramic structure.

When the shortest distance in the thickness direction from the internal electrode to the second ceramic layer (the shortest distance from the internal electrode) is 0, the second ceramic layer is in contact with the internal electrode in the thickness direction.

The shortest distance in the thickness direction from the internal electrode to the second ceramic layer is, for example, preferably 0 μm to 150 μm, more preferably 0 μm to 120 μm.

The thickness of the second ceramic layer is, for example, preferably 3 μm to 75 μm, more preferably 5 μm to 60 μm.

The shortest distance from the internal electrode and the thickness of the second ceramic layer are not limited to the above ranges, and may be adjusted to satisfy the relationship. When the shortest distance is 0, that is, when the second ceramic layer is in contact with the internal electrode, the value of (the shortest distance from the internal electrode)/(the thickness of the second ceramic layer) is always 0 regardless of the thickness of the second ceramic layer. In this case, the thickness of the second ceramic layer is preferably 3 μm to 75 μm.

The compositions of the amorphous portions and the compositions of crystals in the first and second ceramic layers, and the crystal contents of the first and second ceramic layers can be the same as those of the first glass-ceramic structure.

In the second glass-ceramic structure, the percentage of the cross-sectional area of the crystals in the second ceramic layer relative to the cross-sectional area of the second ceramic layer is greater than the percentage of the cross-sectional area of the crystals in the first ceramic layer relative to the cross-sectional area of the first ceramic layer by a difference (d2) of 10 area % to 75 area %.

When the difference (d2) is 10 area % to 75 area %, structural defects and deterioration occurring around the internal electrodes can be reduced or prevented compared to when the difference (d2) is outside the above range.

The internal electrodes, via conductors, and external electrodes can be formed using a conductive paste containing Ag or Cu. In the second glass-ceramic structure, the internal electrodes, via conductors, and external electrodes preferably include Cu as a main component. The internal electrodes, via conductors, and external electrodes can be formed by printing using a metal mask or by transferring and laminating a Cu pattern.

The second glass-ceramic structure can be produced by the following method, for example.

The green sheets A and B can be produced in the same manner as in the production of the first glass-ceramic structure. The internal electrodes, via conductors, and external electrodes are formed on/in one or some of the green sheets A using, for example, a conductive paste containing Ag or Cu.

The green sheets A are stacked and the green sheets B are disposed on the opposing surfaces of the stack, one on each surface, to produce a multilayer green sheet. The multilayer green sheet is fired so that the green sheets A and B are reacted. Thereby, crystals are generated in the entire or part of the laminate surface of the green sheets B. As a result, the glass-ceramic structure shown in FIG. 4 is obtained.

The multilayer green sheet is fired at 1000° C. or lower as in the production of the first glass-ceramic structure. The multilayer green sheet may be fired in any atmosphere. Yet, when a material resistant to oxidation, such as Ag, is used to form the internal electrodes and the like, an air atmosphere is preferred; while when a material prone to oxidation, such as Cu, is used, a hypoxic atmosphere such as a nitrogen atmosphere is preferred. The multilayer green sheet may be fired in a reducing atmosphere.

In the second glass-ceramic structure having the above-described configuration, the regions where the second ceramic layers are formed have higher fracture toughness. Disposing the second ceramic layer in the vicinity of or adjacent to an internal electrode can prevent propagation of cracks toward the internal electrode when a structural defect such as an internal fracture occurs in the first ceramic layer, thereby preventing or reducing a decrease in reliability caused by issues such as short circuit and disconnection.

The electronic component of the present disclosure is described below.

The electronic component of the present disclosure includes the first glass-ceramic structure of the present disclosure and/or the second glass-ceramic structure of the present disclosure.

The electronic component of the present disclosure includes, for example, a multilayer ceramic substrate such as the first glass-ceramic structure or the second glass-ceramic structure, and a chip component mounted on the multilayer ceramic substrate. Examples of the chip component include LC filters, capacitors, inductors, patch antennas, couplers, and laminated baluns.

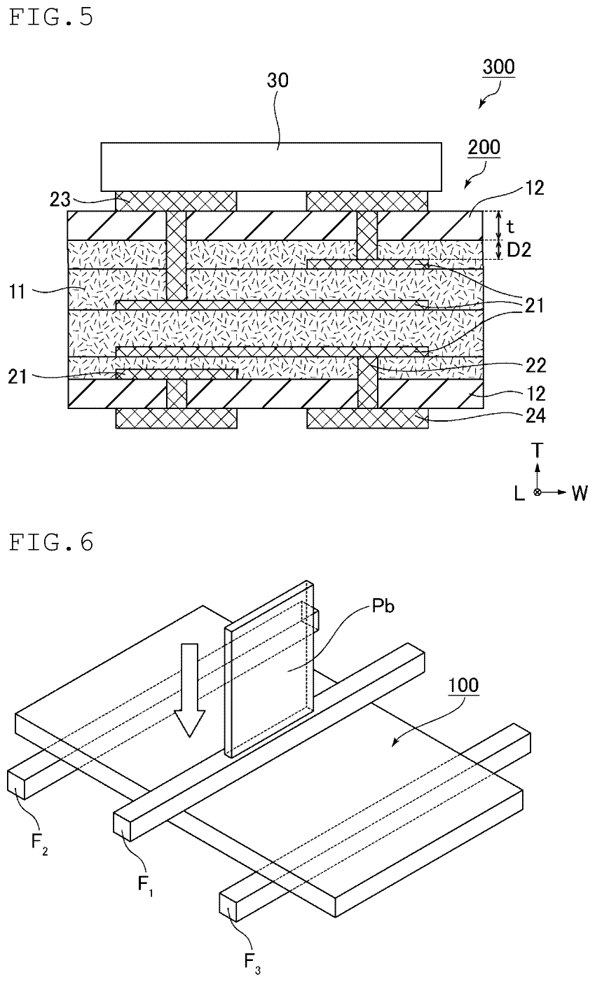

FIG. 5 is a schematic cross-sectional view of an example of the electronic component. A chip component 30 may be mounted on the glass-ceramic structure (multilayer ceramic substrate) 200 while being electrically connected to the external electrodes 23. Thus, an electronic component 300 including the glass-ceramic structure 200 is provided.

The electronic component 300 may be mounted on a mounting board (e.g., motherboard) such that they are electrically connected to each other via the external electrodes 24.

An example is described in which the second glass-ceramic structure is used as a multilayer ceramic substrate, but the first glass-ceramic structure and the second glass-ceramic structure each may also be used as a chip component to be mounted on a multilayer ceramic substrate. In other words, the first glass-ceramic structure and the second glass-ceramic structure each may be used as a component such as an LC filter, a capacitor, an inductor, a patch antenna, a coupler, or a laminated balun.

The first glass-ceramic structure and the second glass-ceramic structure each may also be used as a component other than the multilayer ceramic substrate and chip component.

### EXAMPLES

The following describes examples that more specifically disclose the glass-ceramic structure of the present disclosure. The present disclosure is not limited to these examples.

### Production of Glass-Ceramic Structure

### (A) Production of Green Sheet A

A glass frit having a composition of B₂O₃/SiO₂/Al₂O₃/ZnO/CuO was mixed with SiO₂ quartz powder to prepare a raw material powder mixture having a composition after firing consisting of 74.21 wt % of SiO₂, 10.76 wt % of B₂O₃, 6.03 wt % of Al₂O₃, 6.02 wt % of ZnO, 0.47 wt % of CuO, and 2.50 wt % of BaO (a composition 1 in Table 5), which were based on oxides.

The raw material powder mixture was mixed with a toluene/ethanol solvent mixture and a dispersant, and they were mixed in a ball mill with PSZ balls (diameter: 5 mm). To the mixture were added a plasticizer and a solution of a butyral binder in a toluene/ethanol solvent mixture, followed by mixing. Thus, a desired slurry was obtained. The slurry was applied to a carrier film using a doctor blade and dried to give a green sheet A having a thickness after firing of 20 μm.

### (B) Production of Green Sheets B1 to B4

A powder mixture was prepared by mixing the same glass frit as that used in the green sheet A in an amount of 10 wt % to 95 wt % with Al₂O₃ (in the case of a green sheet B1), ZnO (in the case of a green sheet B2), Mg₂SiO₄ (in the case of a green sheet B3), or BaTiO₃ (in the case of a green sheet B4) as a filler component in an amount of 5 wt % to 90 wt %.

The powder mixture was mixed in a ball mill with PSZ balls (diameter: 5 mm). To the powder mixture were added a plasticizer and a solution of a butyral binder in a toluene/ethanol solvent mixture, followed by mixing. Thus, a desired slurry was obtained. The slurry was applied to a carrier film using a doctor blade and dried. Thereby, green sheets B1 to B4 were obtained. For each of the green sheets B1 to B4, green sheets having thicknesses after firing of 5, 10, and 50 μm were obtained.

### (C) Production of Glass-Ceramic Structure

A glass-ceramic structure was produced by the following procedure. Fifty green sheets A (78 mm×58 mm), obtained by cutting, were stacked. As shown in FIG. 1 or FIG. 2, two green sheets B1 having the same dimensions, obtained by cutting, were disposed on the opposing surfaces of the stack of the green sheets A, one on each surface, or the green sheets B1 were disposed at distances of 50 μm or 100 μm from the surfaces of the stack of the green sheets A in the thickness direction.

The stack was subjected to isostatic pressing at 160 MPa to produce a consolidated body. The consolidated body was cut into pieces (35 mm×6 mm). The pieces were then fired in a reducing atmosphere at 900° C. or higher and 1000° C. or lower for 60 minutes or longer to obtain desired glass-ceramic structures (hereinafter also referred to as specimens). For each of the green sheets B2 to B4, specimens were prepared in the same manner as described above.

### (D) Observation of Cross Section of Glass-Ceramic Structure

A cross section of each specimen prepared above was exposed using a blade dicing. Using energy dispersive X-ray analysis (EDX) and X-ray diffraction (XRD), layers with crystal contents differing across the layers were observed in the vicinity of the region where any of the green sheets B1 to B4 was disposed. In the layers with different crystal contents, crystals present in a different content and/or crystals absent from the stack of the green sheets A and precipitated only in the layers with different crystal contents were observed.

In the specimen including the green sheet B1, Al₂O₃, BaAl₂Si₂O₈, and ZnAl₂O₄ crystals increased.

In the specimen including the green sheet B2, ZnAl₂O₃, ZnO, and Zn₂SiO₄ crystals increased.

In the specimen including the green sheet B3, Mg₂SiO₄, MgSiO₃, and MgO crystals increased.

In the specimen including the green sheet B4, ZnTiO₃, Al₂TiO₅, BaAl₂Si₂O₈, and TiO₂ crystals increased.

The flexural strength was measured and evaluated for specimens in which the percentage of the cross-sectional area of crystals relative to the cross-sectional area was greater by 5 area %, 10 area %, 40 area %, or 75 area % compared to the surrounding layer(s).

The percentage of the cross-sectional area of crystals was calculated as follows. First, a cross section of the specimen was observed using a scanning electron microscope (SEM), and crystalline portions and amorphous portions were marked with specific colors. The marked crystalline portions were extracted using image analysis software (ImageJ), black and white binarization was performed, and then, the cross-sectional area of the crystalline portions and the cross-sectional area of the amorphous portions were determined. The percentage of the cross-sectional area of crystals in the cross-sectional area of the specimen was calculated by dividing the cross-sectional area of the crystalline portions by the sum of the cross-sectional area of the crystalline portions and the cross-sectional area of the amorphous portions.

### (E) Measurement of Flexural Strength

Using the same procedure as described above, a specimen for measuring flexural strength with a length of 35 mm, a width of 6 mm, and a thickness of 0.6 mm was prepared, and the flexural strength was measured. Specifically, as shown in FIG. 6, while the specimen (the glass-ceramic structure 100) was supported from below with two supporting points F₂ and F₃, a probe Pb was lowered onto the center of the specimen, and the pressing force at which the specimen broke was measured and taken as the flexural strength. The distance between a supporting point F₁ and the supporting point F₂ and the distance between the supporting points F₁ and F₃ were each set to 20 mm, and the pressing speed was 1 mm/min. The measurement was carried out using AUTOGRAPH AGX-5kNX (Shimadzu Corporation). FIG. 6 is a perspective view showing a method for measuring the flexural strength of the glass-ceramic structure produced in the Examples.

Specimens having a flexural strength ratio not lower than 120% of the flexural strength, which was taken as 100%, of a reference specimen produced by stacking only green sheets A and firing the stack were determined to have the effect of the green sheet B. Tables 1 to 4 show the results.

Table 1 shows the following results for a specimen including the green sheet(s) B1: the increased percentage of the cross-sectional area of the crystals in the second ceramic layer compared to the first ceramic layer; the thickness (t) of the second ceramic layer; the distance (D1) between the second ceramic layer and a surface of the specimen; the percentage of flexural strength of the specimen; and (D1)/(t).

As in Table 1, Tables 2 to 4 show the results for specimens including the green sheets B2 to B4.

TABLE 1

| | | | Shortest | | |
|---|---|---|---|---|---|
| | | | distance | | |
| | Increased | | from | Flexural | |
| | percentage of | | surface | strength | |
| Green | crystals | Thickness | (D1) | ratio | |
| sheet B1 | (area %) | (t) (μm) | (μm) | (%) | (D1)/(t) |
| Example 1 | 75 | 5 | 0 | 148 | 0 |
| Example 2 | | 10 | 0 | 205 | 0 |
| Example 3 | | 50 | 0 | 189 | 0 |
| Example 4 | | 5 | 50 | 130 | 10 |
| Example 5 | | 10 | 50 | 149 | 5 |
| Example 6 | | 50 | 50 | 154 | 1 |
| Comparative | | 5 | 100 | 108 | 20 |
| Example 1 | | | | | |
| Example 7 | | 10 | 100 | 124 | 10 |
| Example 8 | | 50 | 100 | 139 | 2 |
| Example 9 | 40 | 5 | 0 | 145 | 0 |
| Example 10 | | 10 | 0 | 197 | 0 |
| Example 11 | | 50 | 0 | 183 | 0 |
| Example 12 | | 5 | 50 | 13 | 10 |
| Example 13 | | 10 | 50 | 149 | 5 |
| Example 14 | | 50 | 50 | 147 | 1 |
| Comparative | | 5 | 100 | 108 | 20 |
| Example 2 | | | | | |
| Example 15 | | 10 | 100 | 124 | 10 |
| Example 16 | | 50 | 100 | 143 | 2 |
| Example 17 | 10 | 5 | 0 | 133 | 0 |
| Example 18 | | 10 | 0 | 168 | 0 |
| Example 19 | | 50 | 0 | 170 | 0 |
| Example 20 | | 5 | 50 | 122 | 10 |
| Example 21 | | 10 | 50 | 137 | 5 |
| Example 22 | | 50 | 50 | 141 | 1 |
| Comparative | | 5 | 100 | 105 | 20 |
| Example 3 | | | | | |
| Example 23 | | 10 | 100 | 124 | 10 |
| Example 24 | | 50 | 100 | 133 | 2 |
| Comparative | 5 | 5 | 0 | 115 | 0 |
| Example 4 | | | | | |
| Comparative | | 10 | 0 | 118 | 0 |
| Example 5 | | | | | |
| Comparative | | 50 | 0 | 119 | 0 |
| Example 6 | | | | | |
| Comparative | | 5 | 50 | 116 | 10 |
| Example 7 | | | | | |
| Comparative | | 10 | 50 | 116 | 5 |
| Example 8 | | | | | |
| Comparative | | 50 | 50 | 114 | 1 |
| Example 9 | | | | | |
| Comparative | | 5 | 100 | 101 | 20 |
| Example 10 | | | | | |
| Comparative | | 10 | 100 | 115 | 10 |
| Example 11 | | | | | |
| Comparative | | 50 | 100 | 108 | 2 |
| Example 12 | | | | | |

TABLE 2

| | | | Shortest | | |
|---|---|---|---|---|---|
| | | | distance | | |
| | Increased | | from | Flexural | |
| | percentage | | surface | strength | |
| Green | of crystals | Thickness | (D1) | ratio | |
| sheet B2 | (area %) | (t) (μm) | (μm) | (%) | (D1)/(t) |
| Example 25 | 75 | 5 | 0 | 180 | 0 |
| Example 26 | | 50 | 0 | 213 | 0 |
| Example 27 | | 5 | 50 | 174 | 10 |
| Example 28 | | 50 | 50 | 185 | 1 |
| Comparative | | 5 | 100 | 125 | 20 |
| Example 13 | | | | | |
| Example 29 | | 10 | 100 | 145 | 10 |
| Example 30 | | 50 | 100 | 151 | 2 |
| Example 31 | 10 | 5 | 0 | 152 | 0 |
| Example 32 | | 50 | 0 | 170 | 0 |
| Example 33 | | 5 | 50 | 151 | 10 |
| Example 34 | | 50 | 50 | 140 | 1 |
| Comparative | | 5 | 100 | 120 | 20 |
| Example 14 | | | | | |
| Example 35 | | 10 | 100 | 145 | 10 |
| Example 36 | | 50 | 100 | 149 | 2 |

TABLE 3

| | | | Shortest | | |
|---|---|---|---|---|---|
| | | | distance | | |
| | Increased | | from | Flexural | |
| | percentage of | | surface | strength | |
| Green | crystals | Thickness | (D1) | ratio | |
| sheet B3 | (area %) | (t) (μm) | (μm) | (%) | (D1)/(t) |
| Example 37 | 75 | 5 | 0 | 154 | 0 |
| Example 38 | | 50 | 0 | 165 | 0 |
| Example 39 | | 5 | 50 | 147 | 10 |
| Example 40 | | 50 | 50 | 151 | 1 |
| Comparative | | 5 | 100 | 113 | 20 |
| Example 15 | | | | | |
| Example 41 | | 10 | 100 | 128 | 10 |
| Example 42 | | 50 | 100 | 139 | 2 |
| Example 43 | 10 | 5 | 0 | 129 | 0 |
| Example 44 | | 50 | 0 | 140 | 0 |
| Example 45 | | 5 | 50 | 130 | 10 |
| Example 46 | | 50 | 50 | 140 | 1 |
| Comparative | | 5 | 100 | 101 | 20 |
| Example 16 | | | | | |
| Example 47 | | 10 | 100 | 125 | 10 |
| Example 48 | | 50 | 100 | 138 | 2 |

TABLE 4

| | | | Shortest | | |
|---|---|---|---|---|---|
| | | | distance | | |
| | Increased | | from | Flexural | |
| | percentage of | | surface | strength | |
| Green | crystals | Thickness | (D1) | ratio | |
| sheet B4 | (area %) | (t) (μm) | (μm) | (%) | (D1)/(t) |
| Example 49 | 75 | 5 | 0 | 138 | 0 |
| Example 50 | | 50 | 0 | 135 | 0 |
| Example 51 | | 5 | 50 | 135 | 10 |
| Example 52 | | 50 | 50 | 139 | 1 |
| Example 17 | | 5 | 100 | 108 | 20 |
| Example 53 | | 10 | 100 | 124 | 10 |
| Example 54 | | 50 | 100 | 125 | 2 |
| Example 55 | 10 | 5 | 0 | 121 | 0 |
| Example 56 | | 50 | 0 | 123 | 0 |
| Example 57 | | 5 | 50 | 129 | 10 |
| Example 58 | | 50 | 50 | 132 | 1 |
| Example 18 | | 5 | 100 | 103 | 20 |
| Example 59 | | 10 | 100 | 124 | 10 |
| Example 60 | | 50 | 100 | 125 | 2 |

As shown in Tables 1 to 4, specimens in which the increased percentage of the cross-sectional area of the crystals was 10 area % to 75 area % and which satisfy the relationship represented by (the shortest distance from each surface)/(the thickness of the second ceramic layer)≤10 were confirmed to have a flexural strength improved by 20% or more compared to a second ceramic layer-free reference specimen. This is believed to be because the localized presence of crystals, which have higher strength than amorphous materials such as glass, imparts localized fracture toughness and enhances strength, and the mixture of materials with different expansion coefficients contributes to distributing external stress. The reason why the strength decreases as the distance from the surface of the ceramic structure increases is believed to be because a region not reinforced increases between the stress application point and the second ceramic layer.

The specimens in which the ceramic composition of the green sheets A is the same as any of the compositions 2 to 7 shown in Table 5 and in which the crystal content of the second ceramic layer(s) is higher than that of the surrounding region by 10 area % to 75 area % also had an improved flexural strength.

TABLE 5

| | Ceramic composition (based on oxide) | | | | | |
|---|---|---|---|---|---|---|
| | SiO₂ | B₂O₃ | Al₂O₃ | ZnO | CuO | BaO |
| Composition 1 | 74.21% | 10.76% | 6.03% | 6.02% | 0.47% | 2.50% |
| Composition 2 | 51.37% | 8.61% | 9.83% | 19.82% | 0.38% | 10.00% |
| Composition 3 | 62.74% | 17.22% | 9.65% | 9.63% | 0.75% | 0.00% |
| Composition 4 | 77.44% | 9.04% | 5.07% | 5.06% | 3.39% | 0.00% |
| Composition 5 | 61.50% | 10.51% | 14.00% | 14.00% | 0.00% | 0.00% |
| Composition 6 | 47.20% | 16.96% | 17.12% | 18.72% | 0.00% | 0.00% |
| Composition 7 | 77.44% | 17.22% | 2.62% | 2.72% | 0.00% | 0.00% |

Production of Ceramic Structure including Internal Electrode

### (A) Production of Green Sheet A

A green sheet A was obtained in the same manner as described above, except that the thickness was changed such that the thickness after firing was 5 to 50 μm.

### (B) Production of Green Sheets B1 to B4

The green sheets B1 to B4 were obtained in the same manner as described above.

### (C) Production of Specimen for Measuring Strength

First, 25 green sheets A each having a thickness after firing of 20 μm were stacked, and a green sheet B1 having a thickness after firing of 5 μm, 10 μm, or 50 μm was stacked thereon. Then, a green sheet(s) A was stacked to a thickness of 0 to 50 μm, and internal electrodes (Cu) each having a thickness after firing of 50 μm were formed thereon. The internal electrodes were formed by screen printing using a screen printing plate. Specifically, an appropriate amount of Cu paste was placed on a mask, and the mask and the surface green sheet were brought into contact with each other. Thereafter, the Cu paste was squeezed, and printed onto the green sheet through the mask openings.

Furthermore, a green sheet(s) A was stacked on the internal electrodes to a thickness of 0 to 50 μm, then a green sheet B1 having a thickness after firing of 5 μm, 10 μm, or 50 μm was stacked thereon, and finally 25 green sheets A each having a thickness after firing of 20 μm were stacked thereon to produce a stack.

The stack was subjected to isostatic pressing at 160 MPa to produce a consolidated body. The consolidated body was cut into pieces (5 mm×5 mm). The pieces were then fired in a reducing atmosphere at 900° C. to 1000° C. for 60 minutes or longer to obtain internal-electrode containing ceramic structures as specimens for measuring strength. For each of the green sheets B2 to B4, specimens for measuring strength were prepared in the same manner as described above.

### (D) Strength Measuring Test

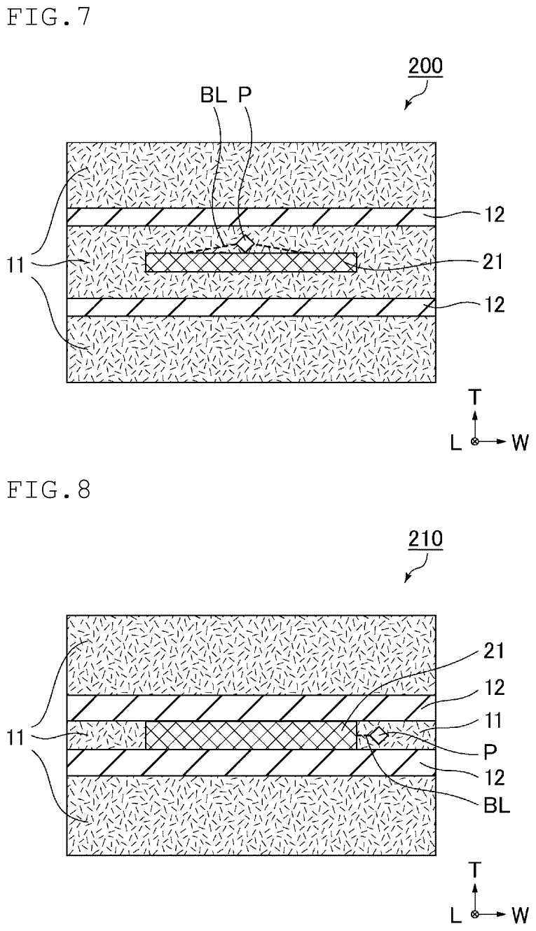

A cross section of the specimen for measuring strength prepared as described above was exposed using a blade dicing. In the case of D2=100, as shown in FIG. 7, a Vickers hardness tester (Matsuzawa Co., Ltd.) was used to make an indentation at a load of 50 gf at a position (point P) about 20 μm away in the thickness direction from the internal electrode 21 observed on the cross section. FIG. 7 is a schematic cross-sectional view showing evaluation of the strength of the glass-ceramic structure produced in the Examples. In the case of D2=0, as shown in FIG. 8, an indentation was made at a position (point P) about 20 μm away in the width direction from the internal electrode 21 observed on the cross section, as in the case of D2=100. FIG. 8 is a schematic cross-sectional view showing evaluation of the strength of the glass-ceramic structure produced in the Examples.

A crack generated in the ceramic portion by making an indentation was indicated by a break line BL. When an indentation was made with a load exceeding the strength of the ceramic portion, the break line BL extends from the indentation toward the internal electrode 21 or the second ceramic layers 12. For each specimen (glass-ceramic structure 200), whether the break line BL reached the internal electrode 21 was examined.

The same experiment was also carried out for a structure including internal electrodes and a ceramic portion made only of green sheets A, without any of green sheets B1 to B4 (Comparative Example 19). Table 6 shows the results.

TABLE 6

| | | Increased | | Distance | | |
|---|---|---|---|---|---|---|
| | | percentage of | | from top | | State |
| | Green | crystals | Thickness | surface | | of break |
| | sheet | (area %) | (t) (μm) | (D2) (μm) | (D2)/(t) | line |
| Comparative | — | 0% | — | — | — | Reached Cu |
| Example 19 | | | | | | |
| Example 61 | B1 | 75% | 5 | 0 | 0 | Did not reach Cu |
| Example 62 | | | 50 | 0 | 0 | Did not reach Cu |
| Comparative | | | 5 | 100 | 20 | Reached Cu |
| Example 20 | | | | | | |
| Example 63 | | | 10 | 100 | 10 | Did not reach Cu |
| Example 64 | | | 50 | 100 | 2 | Did not reach Cu |
| Example 65 | B2 | | 5 | 0 | 0 | Did not reach Cu |
| Example 66 | | | 50 | 0 | 0 | Did not reach Cu |
| Comparative | | | 5 | 100 | 20 | Reached Cu |
| Example 21 | | | | | | |
| Example 67 | | | 10 | 100 | 10 | Did not reach Cu |
| Example 68 | | | 50 | 100 | 2 | Did not reach Cu |
| Example 69 | B3 | | 5 | 0 | 0 | Did not reach Cu |
| Example 70 | | | 50 | 0 | 0 | Did not reach Cu |
| Comparative | | | 5 | 100 | 20 | Reached Cu |
| Example 22 | | | | | | |
| Example 71 | | | 10 | 100 | 10 | Did not reach Cu |
| Example 72 | | | 50 | 100 | 2 | Did not reach Cu |
| Example 73 | B4 | | 5 | 0 | 0 | Did not reach Cu |
| Example 74 | | | 50 | 0 | 0 | Did not reach Cu |
| Comparative | | | 5 | 100 | 20 | Reached Cu |
| Example 23 | | | | | | |
| Example 75 | | | 10 | 100 | 10 | Did not reach Cu |
| Example 76 | | | 50 | 100 | 2 | Did not reach Cu |
| Example 77 | B1 | 10% | 5 | 0 | 0 | Did not reach Cu |
| Example 78 | | | 50 | 0 | 0 | Did not reach Cu |
| Comparative | | | 5 | 100 | 20 | Reached Cu |
| Example 24 | | | | | | |
| Example 79 | | | 10 | 100 | 10 | Did not reach Cu |
| Example 80 | | | 50 | 100 | 2 | Did not reach Cu |
| Example 81 | B2 | | 5 | 0 | 0 | Did not reach Cu |
| Example 82 | | | 50 | 0 | 0 | Did not reach Cu |
| Comparative | | | 5 | 100 | 20 | Reached Cu |
| Example 25 | | | | | | |
| Example 83 | | | 10 | 100 | 10 | Did not reach Cu |
| Example 84 | | | 50 | 100 | 2 | Did not reach Cu |
| Example 85 | B3 | | 5 | 0 | 0 | Did not reach Cu |
| Example 86 | | | 50 | 0 | 0 | Did not reach Cu |
| Comparative | | | 5 | 100 | 20 | Reached Cu |
| Example 26 | | | | | | |
| Example 87 | | | 10 | 100 | 10 | Did not reach Cu |
| Example 88 | | | 50 | 100 | 2 | Did not reach Cu |
| Example 89 | B4 | | 5 | 0 | 0 | Did not reach Cu |
| Example 90 | | | 50 | 0 | 0 | Did not reach Cu |
| Comparative | | | 5 | 100 | 20 | Reached Cu |
| Example 27 | | | | | | |
| Example 91 | | | 10 | 100 | 10 | Did not reach Cu |
| Example 92 | | | 50 | 100 | 2 | Did not reach Cu |

As shown in Table 6, in Comparative Example 19, in which no second ceramic layer was used, and in Comparative Examples 20 to 27, in which the value of (the shortest distance from the internal electrode)/(the thickness of the second ceramic layer) was 20, the break line reached the internal electrode, whereas in Examples 61 to 92, in which the relationship represented by (the shortest distance from the internal electrode)/(the thickness of the second ceramic layer)≤10 was satisfied, the break line did not reach the internal electrode. For the ceramic structures of Examples 61 to 92, like the ceramic structures of Examples 1 to 60, the localized presence of crystals, which have higher strength than amorphous materials such as glass, is considered to impart localized fracture toughness to enhance the strength, and the mixture of materials with different expansion coefficients contributes to distributing external stress. Thus, when a structural defect occurs, propagation of cracks toward the internal electrode can be prevented even after a heat cycle test or the like, thereby preventing or reducing a decrease in reliability caused by issues such as short circuit and disconnection.

The ceramic composition of the green sheet A used in Examples 61 to 92 and Comparative Examples 19 to 27 is the same as the composition 1 in Table 5. When the ceramic composition of the green sheet A is the same as any of the compositions 2 to 7 shown in Table 5, and the crystal content of the second ceramic layers is higher than that of the first ceramic layers by 10 area % to 75 areas, the break line did not reach the internal electrode like in Examples 61 to 92.

### REFERENCE SIGNS LIST

11 first ceramic layer
12 second ceramic layer
13, 13a, 13b, 13c, 13d crystals
21 internal electrode
22 via conductor
23, 24 external electrode
30 chip component
100, 100A, 100B, 100C, 110 first glass-ceramic structure
100a one of main surfaces of first glass-ceramic
structure
100b the other main surface of first glass-ceramic
structure
200 second glass-ceramic structure
300 electronic component
t thickness of second ceramic layer
D1 shortest distance from surface
D2 shortest distance from internal electrode
BL break line
F₁, F₂, F₃ supporting point
P indentation
Pb probe

1. A glass-ceramic structure comprising:
at least one first ceramic layer containing first crystals; and
a second ceramic layer containing second crystals,
a first crystal content of the first ceramic layer being different from a second crystal content of the second ceramic layer,
the second ceramic layer being between first ceramic layers of the at least one first ceramic layer in a thickness direction of the glass-ceramic structure, or on a surface of the glass-ceramic structure,
a shortest distance in the thickness direction from the surface of the glass-ceramic structure to the second ceramic layer and a thickness of the second ceramic layer satisfying a relationship (the shortest distance from the surface)/(the thickness of the second ceramic layer)≤10,
the first ceramic layer having a composition of SiO₂: 45 wt % to 77.5 wt %, B₂O₃: 5 wt % to 20 wt %, Al₂O₃: 2.6 wt % to 20 wt %, ZnO: 2.7 wt % to 20 wt %, CuO: 0 wt % to 3.4 wt %, and BaO: 0 wt % to 10 wt %,
the first and second crystals including at least one type of crystals selected from Al₂O₃, Zn₂SiO₄, ZnO, ZnAl₂O₄, BaAl₂Si₂O₈, ZnTiO₃, Al₂TiO₅, TiO₂, Mg₂SiO₄, MgSiO₃, and MgO, and a percentage of a cross-sectional area of the second crystals in the second ceramic layer relative to a cross-sectional area of the second ceramic layer being greater than a percentage of a cross-sectional area of the first crystals in the first ceramic layer relative to a cross-sectional area of the first ceramic layer by a difference of 10 area % to 75 area %.

2. The glass-ceramic structure according to claim 1, wherein the first and second crystals include two or more types of crystals.

3. The glass-ceramic structure according to claim 1, wherein the glass-ceramic structure includes two second ceramic layers.

4. The glass-ceramic structure according to claim 3, wherein each of the two second ceramic layers are on opposed surfaces of the glass-ceramic structure.

5. The glass-ceramic structure according to claim 3, wherein each of the two second ceramic layers are between the first ceramic layers.

6. The glass-ceramic structure according to claim 1, wherein the second ceramic layer is on the surface of the glass-ceramic structure.

7. The glass-ceramic structure according to claim 1, wherein the second ceramic layer is between the first ceramic layers.

8. The glass-ceramic structure according to claim 1, wherein the shortest distance in the thickness direction from the surface of the glass-ceramic structure to the second ceramic layer is 0 μm to 150 μm.

9. The glass-ceramic structure according to claim 1, wherein the thickness of the second ceramic layer is 3 μm to 75 μm.

10. The glass-ceramic structure according to claim 1, wherein the first crystals include one or more of Al₂O₃ and ZnO crystals, and the second crystals include one or more of Zn₂SiO₄, ZnAl₂O₄, BaAl₂Si₂O₈, ZnTiO₃, Al₂TiO₅, TiO₂, Mg₂SiO₄, MgSiO₃, and MgO.

11. An electronic component comprising the glass-ceramic structure according to claim 1.

12. A glass-ceramic structure comprising:
first ceramic layers containing first crystals;
a second ceramic layer containing second crystals; and
an internal electrode,
a first crystal content of each of the first ceramic layers being different from a second crystal content of the second ceramic layer,
the second ceramic layer being between the first ceramic layers in a thickness direction of the glass-ceramic structure, or on a surface of the glass-ceramic structure,
the second ceramic layer and the internal electrode being adjacent to each other in the thickness direction, or at least one of the first ceramic layers being between the second ceramic layer and the internal electrode in the thickness direction,
a shortest distance in the thickness direction from the internal electrode to the second ceramic layer and a thickness of the second ceramic layer satisfying a relationship (the shortest distance from the internal electrode)/(the thickness of the second ceramic layer)≤10,
the first ceramic layer having a composition of Sio: 45 wt % to 77.5 wt %, B₂O₃: 5 wt % to 20 wt %, Al₂O₃: 2.6 wt % to 20 wt %, ZnO: 2.7 wt % to 20 wt %, CuO: 0 wt % to 3.4 wt %, and BaO: 0 wt % to 10 wt %,
the first and second crystals including at least one type of crystals selected from Al₂O₃, Zn SiO₄, ZnO, ZnAl₂O₄, BaAl₂Si₂O₈, ZnTiO₃, Al₂TiO₅, TiO₂, Mg₂SiO₄, MgSiO₃, and MgO,
a percentage of a cross-sectional area of the second crystals in the second ceramic layer relative to a cross-sectional area of the second ceramic layer is greater than a percentage of a cross-sectional area of the first crystals in the first ceramic layer relative to a cross-sectional area of the first ceramic layer by a difference of 10 area % to 75 area %.

13. The glass-ceramic structure according to claim 12, wherein the first and second crystals include two or more types of crystals.

14. The glass-ceramic structure according to claim 12, wherein the glass-ceramic structure includes two second ceramic layers, and the internal electrode is disposed between the two second ceramic layers in the thickness direction.

15. The glass-ceramic structure according to claim 12, wherein the second ceramic layer is on the surface of the glass-ceramic structure.

16. The glass-ceramic structure according to claim 12, wherein the second ceramic layer is between the first ceramic layers.

17. The glass-ceramic structure according to claim 12, wherein the shortest distance in the thickness direction from the surface of the glass-ceramic structure to the second ceramic layer is 0 μm to 150 μm.

18. The glass-ceramic structure according to claim 12, wherein the thickness of the second ceramic layer is 3 μm to 75 μm.

19. The glass-ceramic structure according to claim 12, wherein the first crystals include one or more of Al₂O₃ and ZnO crystals, and the second crystals include one or more of Zn₂SiO₄, ZnAl₂O₄, BaAl₂Si₂O₈, ZnTiO₃, Al₂TiO₅, TiO₂, Mg₂SiO₄, MgSiO₃, and MgO.

20. An electronic component comprising the glass-ceramic structure according to claim 12.
